(19) United States
(12) Patent Application Publication
(10) Pub. No.: US 2026/0314029 A1
(43) Pub. Date: Oct. 8, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Ka-Hing FUNG, Hsinchu (TW)

(21) Appl. No.: 19/170,065

(22) Filed: Apr. 4, 2025

(51) Int. Cl. H10D 84/01; H10D 84/83

(52) U.S. Cl. CPC H10D 84/0151; H10D 84/832

(57) ABSTRACT

Embodiments of the present disclosure provide a semiconductor device structure that includes an active region, an isolation region disposed alongside the active region, a gate structure over the active region, an interlayer dielectric (ILD) layer disposed over the isolation region, wherein the ILD layer has a dielectric constant that is about 3 to about 5, and an etch stop layer disposed between the ILD layer and the isolation region, wherein the isolation region comprises a nitride-containing dielectric layer, and wherein a width of the isolation region is less than 10 nm.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 5, and 6 and FIGS. 2-4 are perspective views and cross-sectional side views, respectively, of various stages of manufacturing a semiconductor device structure, in accordance with some embodiments.

FIGS. 7A, 8A, 9A, 10A, 11A, 12A, 13A, 14A, and 15A are cross-sectional side views of various stages of manufacturing the semiconductor device structure taken along line A-A of FIG. 6, in accordance with some embodiments.

FIGS. 7B, 8B, 9B, 10B, 11B, 12B, 13B, 14B, and 15B are cross-sectional side views of various stages of manufacturing the semiconductor device structure taken along line B-B of FIG. 6, in accordance with some embodiments.

FIGS. 7C, 8C, 9C, 12C, 13C, 14C, and 15C are cross-sectional side views of various stages of manufacturing the semiconductor device structure taken along line C-C of FIG. 6, in accordance with some embodiments.

FIGS. 12D, 13D, 14D, and 15D are cross-sectional side views of various stages of manufacturing the semiconductor device structure taken along line D-D of FIGS. 12B, 13B, 14B, and 15B, respectively, in accordance with some embodiments.

FIGS. 16A, 17A, and 18A are cross-sectional side views of various stages of manufacturing the semiconductor device structure taken along line A-A of FIG. 6, in accordance with some alternative embodiments.

FIGS. 16B, 17B, and 18B are cross-sectional side views of various stages of manufacturing the semiconductor device structure taken along line B-B of FIG. 6, in accordance with some alternative embodiments.

FIGS. 16C, 17C, and 18C are cross-sectional side views of various stages of manufacturing the semiconductor device structure taken along line C-C of FIG. 6, in accordance with some alternative embodiments.

FIGS. 16D, 17D, and 18D are cross-sectional side views of various stages of manufacturing the semiconductor device structure taken along line D-D of FIGS. 16B, 17B, and 18B, respectively, in accordance with some alternative embodiments.

FIG. 19 is a cross-sectional side view of another stage of manufacturing the semiconductor device structure taken along line C-C of FIG. 6, in accordance with some alternative embodiments.

FIG. 20 is a top view of the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

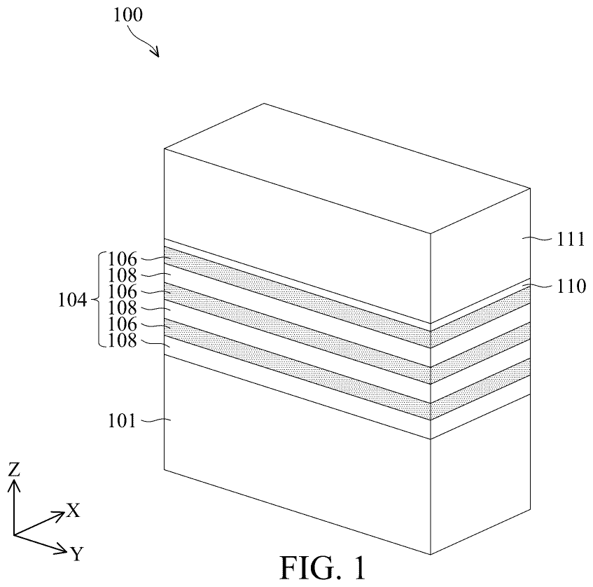

FIGS. 1-20 show exemplary processes for manufacturing a semiconductor device structure 100 according to embodiments of the present disclosure. It is understood that additional operations can be provided before, during, and after processes shown by FIGS. 1-20, and some of the operations described below can be replaced or eliminated, for additional embodiments of the method. The order of the operations/processes is not limiting and may be interchangeable.

FIGS. 1, 5, and 6 and FIGS. 2-4 are perspective views and cross-sectional side views, respectively, of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm, such as from about 3 nm to about 10 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

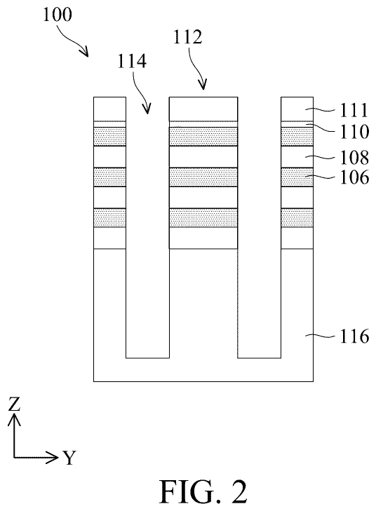

In FIG. 2, fin structures 112 are formed from the stack of semiconductor layers 104. The fin structures 112 defined by the semiconductor layers 104 may be referred to as active region(s). Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combinations thereof.

In some embodiments, the etching process includes a fixed size (shallow trench isolation) STI etch, which also may be referred to as a fixed pitch or fixed CD STI etch. As will become apparent in the description that follows, the fixed size STI etch provides for the fabrication of non-flowable isolation regions because, without using flowable materials, there is not an ability to manage gaps with a range of different sizes (e.g., small size and big size). Therefore, instead of performing an STI etch that covers various different spacings between active regions, the etching process disclosed herein uses a fixed size that leaves an area that is not etched, which results in a dummy device (e.g., dummy fin) positioned laterally between two isolation features, and optionally includes an extra process step to add a dielectric layer in place of the dummy device. When the isolation regions are formed, the thickness of the fill layer is just enough to fill the trenches defined by the STI etch with potential for a small seam in the center, which is not problematic for the performance of the resulting structure.

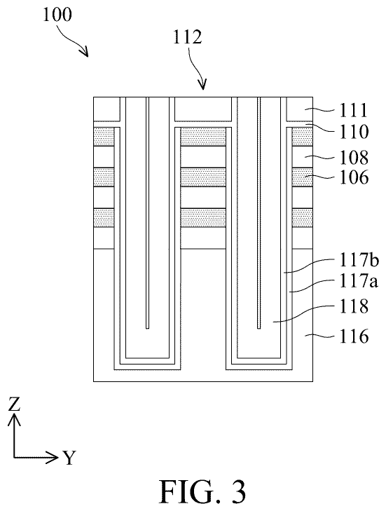

In FIG. 3, a silicon liner 117a may be formed on sidewalls and bottoms of the trenches 114. The silicon liner 117a may be formed by deposition of a silicon-containing material. In some embodiments, the deposition of the silicon-containing material includes a conformal deposition process, such as atomic layer deposition (ALD). The silicon liner 117a may be formed by a selective process such that the silicon-containing material of the silicon liner 117a is formed only on semiconductor material surfaces (e.g., substrate 101, first and second semiconductor layers 106, 108) and not formed on other surfaces (e.g., oxide layer 110, nitride layer 111). An oxide liner 117b may be formed over the silicon liner 117a on the sidewalls and bottoms of the trenches 114 and over the nitride layer 111, although in FIG. 3 the oxide liner 117b is not shown to extend over the nitride layer 111 because the particular process stage being illustrated in FIG. 3 is after planarization, as described below. The oxide liner 117b may be formed by deposition of an oxide-containing material, such as SiO₂. In some embodiments, the deposition of the oxide-containing material includes a conformal deposition process, such as ALD.

After the oxide liner 117b is formed, an insulating material 118 is formed on the substrate 101 and over the oxide liner 117b. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of a nitride-containing material, such as silicon nitride, silicon oxynitride (SiON), SiOCN, SiCN, a low-K nitride dielectric material, or any suitable nitride dielectric material. In some embodiments, the insulating material 118 includes SiO₂, such as SiO₂ formed using a non-flowable process. In other words, the SiO₂ may be formed at a temperature less than about 400° C. and without an annealing process. The insulating material 118 may be formed by ALD, or another suitable method, such as chemical vapor deposition (CVD), low-pressure chemical vapor deposition (LPCVD), or plasma enhanced CVD (PECVD). For example, the insulating material 118 is deposited in a form that is not flowable. In some embodiments, the material used for a flowable process to fill the trenches 114 includes oxygen, and an annealing process is performed following the flowable process. The oxygen in the flowable material can cause Ge in the second semiconductor layers 108 to diffuse into the first semiconductor layers 106 when the processing temperature is greater than about 450° C. As a result of Ge diffusion, high interface trap density (Dit) in channel may occur. Thus, to inhibit and/or prevent Ge diffusion caused by oxygen and elevated temperatures, formation of the oxide liner 117b and the insulating material 118 may be performed without annealing. For example, the ALD process can be performed at temperatures less than 400° C., whereas annealing temperatures are above 700° C. Furthermore, the insulating material 118 may be free of oxygen.

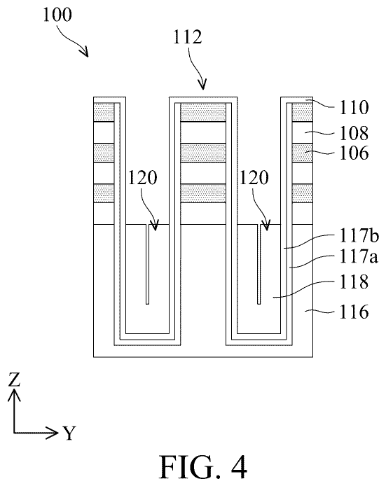

In FIG. 4, the insulating material 118 is recessed to form isolation regions 120 (which also may be referred to herein as “isolation features”). In some embodiments, the isolation regions 120 are the shallow trench isolation (STI) regions. In some embodiments, the isolation regions 120 are nitride-containing dielectric layers. In some embodiments, the isolation regions 120 have a dielectric constant (k value) that is about 3 to about 5. However, in some other embodiments, the k value may be greater than 5, such as about 3 to about 7, or greater than 7. In some embodiments, a width of the isolation regions 120 along the Y direction is less than 10 nm, such as from about 2 nm to about 10 nm. In some embodiments, the width of the isolation regions 120 along the Y direction is greater than a width of the oxide liner 117b in the same direction (which is understood to correspond to a thickness of the oxide liner 117b as formed by the deposition process described above). The structure may include a plurality of isolation regions 120 (e.g., two isolation regions 120 are illustrated in FIG. 4). The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the isolation regions 120 may be level with or below a surface of the second semiconductor layers 108 in contact with the substrate portion 116 formed from the substrate 101. In some embodiments, the process to recess the insulating material 118 also removes the nitride layer 111, as shown in FIG. 4.

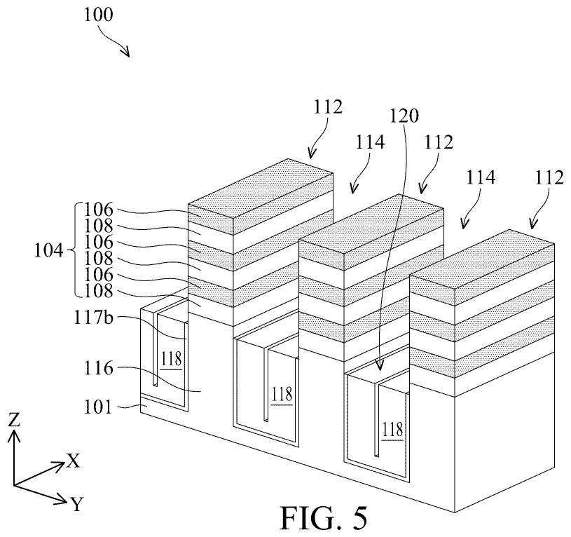

In FIG. 5, the oxide layer 110 (e.g., disposed on the topmost first semiconductor layer 106) is removed. In some embodiments, exposed portions of the oxide liner 117b (e.g., portions of the oxide liner 117b disposed on sidewalls of the trenches 114 above the top surface of the insulating material 118) are also removed. The removal of the oxide layer 110 and the exposed portions of the oxide liner 117b may be performed by a suitable isotropic etching process, such as a dry etching process, a wet etching process, or a combination thereof. In FIG. 5, the silicon liner 117a is omitted for clarity.

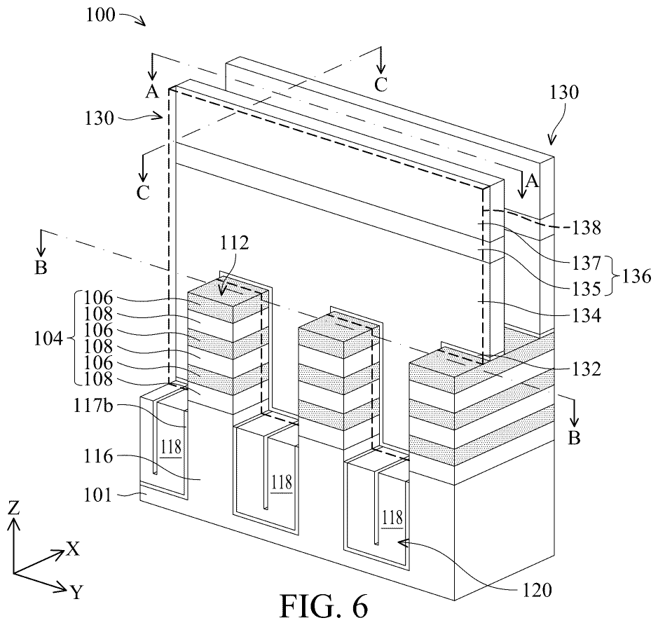

In FIG. 6, one or more sacrificial gate structures 130 (only two are shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Spacers 138 (e.g., shown by a dashed line in the foreground of FIG. 6 as to not block from view the remainder of the respective sacrificial gate structure 130) are then formed on sidewalls of the sacrificial gate structures 130. In some embodiments, the seams in the insulating material 118 are small and the sacrificial gate dielectric layer 132 formed thereon does not fill the seams. The spacers 138 may be formed by conformally depositing one or more layers for the spacers 138 and anisotropically etching the one or more layers, for example. In some embodiments, the spacers 138 are also formed on sidewalls of the exposed portions of the fin structures 112.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer 135 and a nitride layer 137. The spacer 138 may be made of a dielectric material such as silicon oxide, silicon nitride, silicon carbide, silicon oxynitride, SiCN, silicon oxycarbide, SiOCN, and/or combinations thereof. The portions of the fin structures 112 that are covered by the sacrificial gate electrode layer 134 of the sacrificial gate structure 130 serve as channel regions for the semiconductor device structure 100.

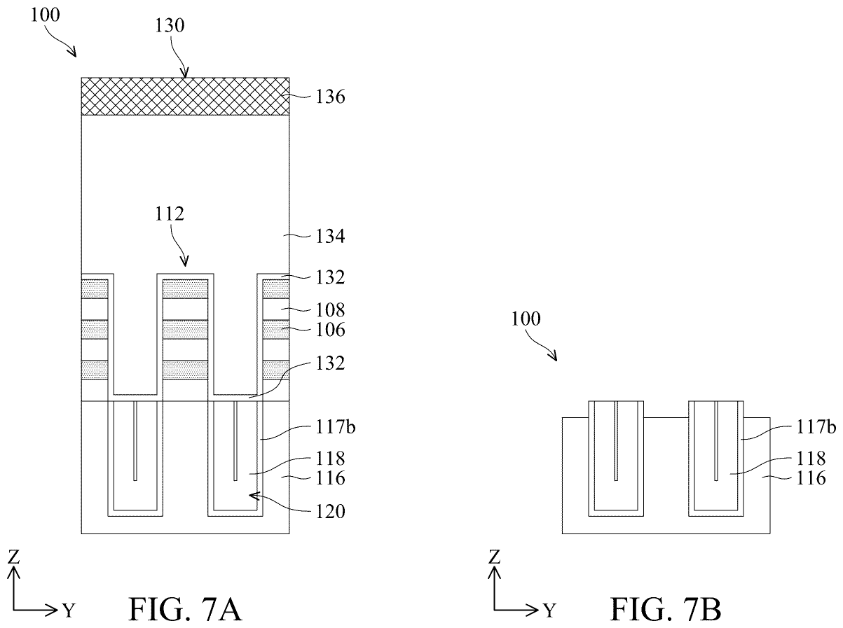

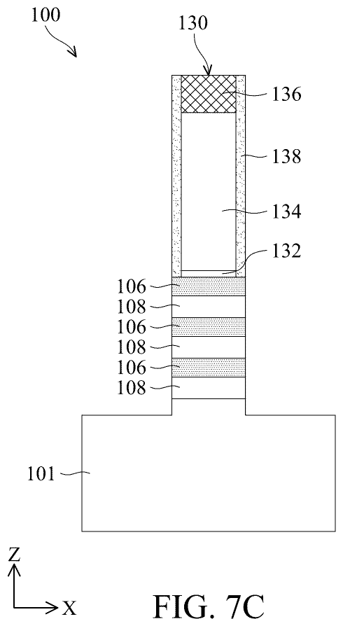

FIGS. 7A, 7B, and 7C are cross-sectional side views of the semiconductor device structure 100 taken along line A-A, line B-B, and line C-C of FIG. 6, respectively. In FIGS. 7A-7C, the portions of the fin structures 112 not covered by the sacrificial gate structure 130 and the spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. In some embodiments, the etch process may remove exposed portions of the silicon liner 117a without removing exposed portions of the oxide liner 117b as shown in FIG. 7B.

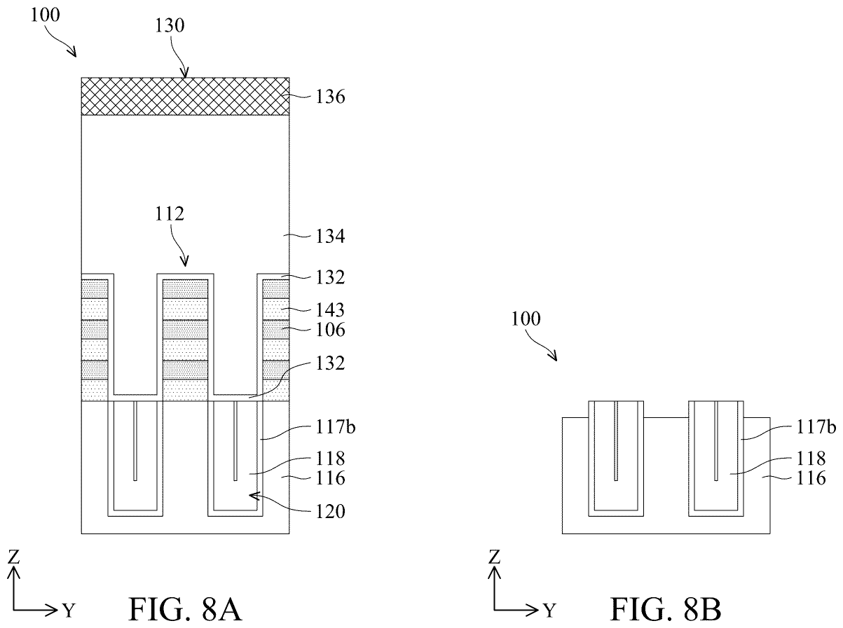

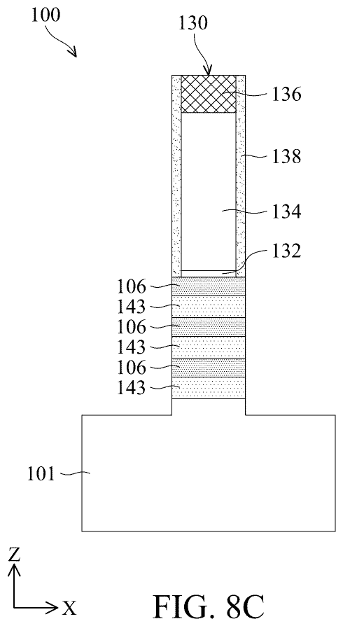

FIGS. 8A, 8B, and 8C are cross-sectional side views of the semiconductor device structure 100 taken along line A-A, line B-B, and line C-C of FIG. 6, respectively. In FIGS. 8A-8C, the second semiconductor layers 108 are removed and replaced with a dielectric material 143. The second semiconductor layers 108 may be removed by a selective etch process, such as a selective dry etch process, a selective wet etch process, or a combination thereof. In some embodiments, the selective etch process does not substantially affect the first semiconductor layers 106. The removal of the second semiconductor layers 108 form openings between vertically adjacent first semiconductor layers 106, and the dielectric material 143 is formed in the openings. The dielectric material 143 may be initially formed in the openings and on the exposed surfaces of the semiconductor device structure 100, and an etch process is performed to remove the portions of the dielectric material 143 not formed in the openings. The etch process may be an anisotropic etch process. At this stage, edge portions of the dielectric material 143 and edge portions of the first semiconductor layers 106 have substantially flat surfaces which may be flush with side surfaces of the spacers 138. In some embodiments, the dielectric material 143 is an oxide formed by any suitable process, such as ALD, CVD, PECVD, or FCVD. In some embodiments, the oxide is silicon oxide.

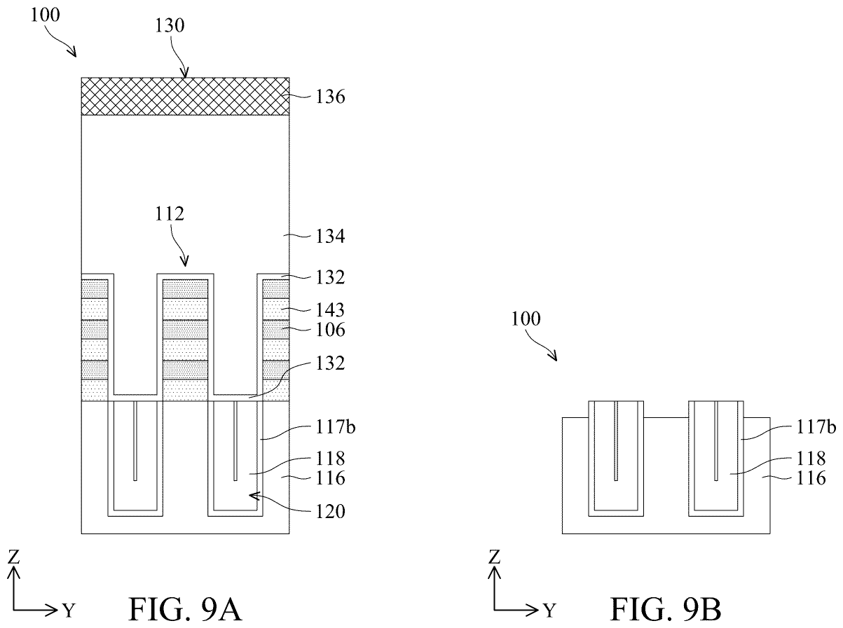

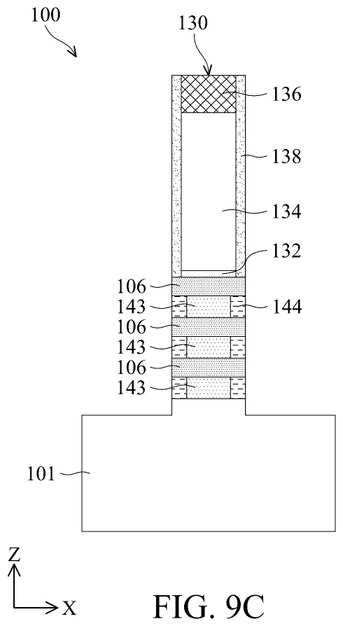

FIGS. 9A, 9B, and 9C are cross-sectional side views of the semiconductor device structure 100 taken along line A-A, line B-B, and line C-C of FIG. 6, respectively. In FIGS. 9A-9C, edge portions of the dielectric material 143 are removed horizontally along the X direction. In other words, the dielectric material 143 is recessed along the X direction. The removal of the edge portions of the dielectric material 143 forms cavities. In some embodiments, the edge portions of the dielectric material 143 are removed by a selective wet etch process. Next, a dielectric layer (not shown) is deposited on the semiconductor device structure 100 and in the cavities. The dielectric layer may be made of a dielectric material, such as SiO, SiON, SiCN, SiOC, SiOCN, or SiN. The dielectric layer may be formed by a conformal deposition process, such as ALD. As shown in FIG. 9C, portions of the dielectric layer are removed to form dielectric spacers 144 in the cavities. In some embodiments, the portions of the dielectric layer are removed by an anisotropic etching process. The dielectric spacers 144 are protected by the first semiconductor layers 106 during the anisotropic etching process. The dielectric material 143 is capped between the dielectric spacers 144 along the X direction, as shown in FIG. 9C.

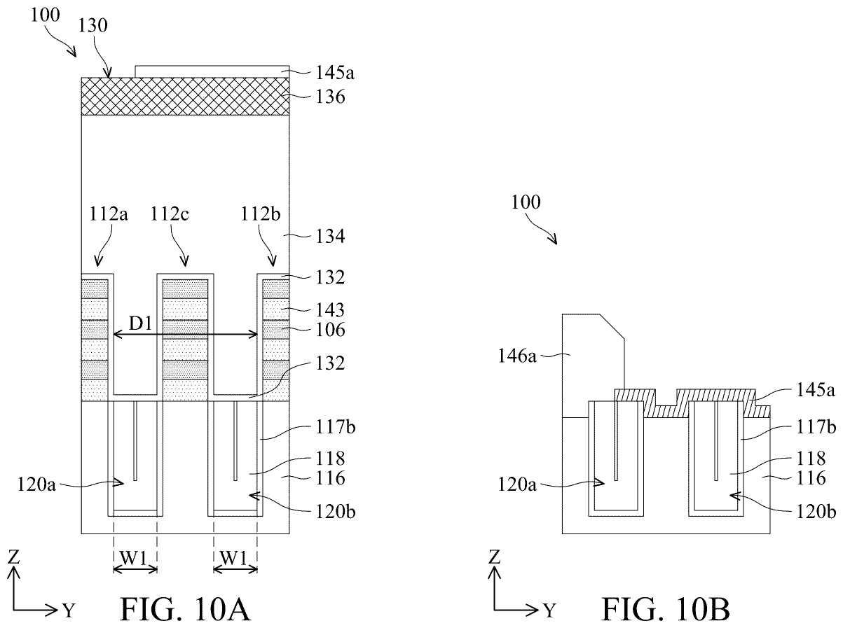

FIGS. 10A and 10B are cross-sectional side views of one of various stages of manufacturing the semiconductor device structure 100 taken along line A-A and line B-B of FIG. 6, respectively, in accordance with some embodiments. There are three fin structures 112 illustrated in FIG. 10A which, in some embodiments, may correspond to a p-channel fin structure 112a, an n-channel fin structure 112b, and a dummy fin structure 112c.

In some embodiments, the p-channel fin structure 112a is a first active region and the n-channel fin structure 112b is a second active region, and the sacrificial gate structure 130 is over the p-channel fin structure 112a and the n-channel fin structure 112b. In some embodiments, a first STI region 120a is disposed adjacent the p-channel fin structure 112a and a second STI region 120b is disposed adjacent the n-channel fin structure 112b. The first and second STI regions 120a, 120b are between the p-channel fin structure 112a and n-channel fin structure 112b and are separated by a substrate portion 116 of the dummy fin structure 112c. As shown in FIG. 10A, in some embodiments, the first and second STI regions 120a, 120b have a first width W1, and a first distance D1 between the p-channel fin structure 112a and n-channel fin structure 112b is greater than two times the first width W1. In some embodiments, the semiconductor device structure 100 further includes a third active region and a fourth active region, and a second distance between the third active region and the fourth active region is different from (e.g., greater or less than) the first distance D1 between the p-channel fin structure 112a (first active region) and the n-channel fin structure 112b (second active region). In such embodiments, a third STI region and a fourth STI region are between the third active region and the fourth active region, and a second width of the third STI region and the fourth STI region may be equal to the first width W1 of the first STI region and the second STI region. This may be referred to as a fixed pitch STI etch in which a plurality of STI regions have the same first width W1 even though the spacing between respective active regions is different.

As shown in FIGS. 10A-10B, a hard mask layer 145a is formed over the n-channel fin structure 112b and over the dummy fin structure 112c while leaving the p-channel fin structure 112a exposed. The hard mask layer 145a may include any suitable material. In some embodiments, the hard mask layer 145a is a metal oxide layer and is formed by an ALD process. The hard mask layer 145a may be initially formed over the entire structure including over the p-channel fin structure 112a, the n-channel fin structure 112b, and the dummy fin structure 112c, and the portion of the hard mask layer 145a formed over the p-channel fin structure 112a may be removed. The portions of the hard mask layer 145a formed over the n-channel fin structure 112b and the dummy fin structure 112c may be protected by a patterned mask (not shown). As shown in FIG. 10B, a p-type source/drain (S/D) feature 146a is formed from the exposed portion of the substrate portion 116 of the p-channel fin structure 112a in the S/D region. No semiconductor material is formed from the substrate portion 116 of the dummy fin structure 112c in the S/D region and the substrate portion 116 of the n-channel fin structure 112b in the S/D region due to the hard mask layer 145a formed thereon, as shown in FIG. 10B. The p-type S/D feature 146a may be made of one or more layers of Si, SiGe, and Ge. For p-channel FETs, p-type dopants, such as boron (B), may also be included in the p-type S/D feature 146a. After forming the p-type S/D feature 146a, the hard mask layer 145a is removed. The hard mask layer 145a may be removed by any suitable process, such as a dry etch process, a wet etch process, or a combination thereof.

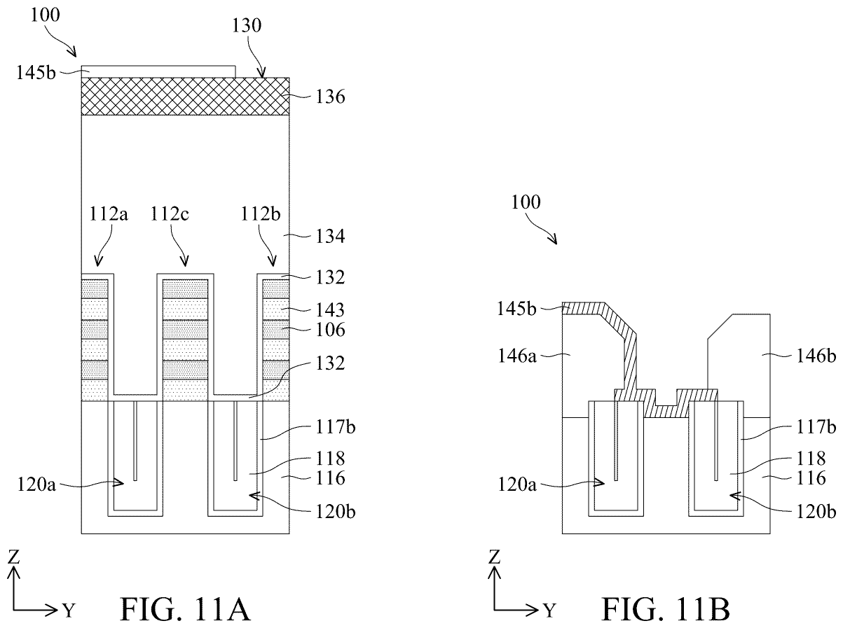

As shown in FIGS. 11A-11B, a hard mask layer 145b is formed over the p-channel fin structure 112a, the dummy fin structure 112c, and the p-type S/D feature 146a while leaving the n-channel fin structure 112b exposed. The hard mask layer 145b may include any suitable material. In some embodiments, the hard mask layer 145b is a metal oxide layer and is formed by an ALD process. The hard mask layer 145b may be initially formed over the entire structure including over the p-channel fin structure 112a, the n-channel fin structure 112b, and the dummy fin structure 112c, and the portion of the hard mask layer 145b formed over the n-channel fin structure 112b may be removed. The portions of the hard mask layer 145b formed over the p-channel fin structure 112a and the dummy fin structure 112c may be protected by a patterned mask (not shown). As shown in FIG. 11B, an n-type S/D feature 146b is formed from the exposed portion of the substrate portion 116 of the n-channel fin structure 112b in the S/D region. No semiconductor material is formed from the substrate portion 116 of the dummy fin structure 112c in the S/D region and the p-type S/D feature 146a due to the hard mask layer 145b formed thereon, as shown in FIG. 11B. The n-type S/D feature 146b may be made of one or more layers of Si, SiP, SiC and SiCP. After forming the n-type S/D feature 146b, the hard mask layer 145b is removed. The hard mask layer 145b may be removed by any suitable process, such as a dry etch process, a wet etch process, or a combination thereof.

The S/D features 146a-b may be formed by an epitaxial growth method using CVD, ALD or MBE. The S/D features 146a-b may grow both vertically and horizontally to form facets, which may correspond to crystalline planes of the material used for the substrate portion 116. In this disclosure, a source feature and a drain feature are interchangeably used, and the structures thereof are substantially the same. Furthermore, source/drain feature(s) may refer to a source or a drain, individually or collectively dependent upon the context.

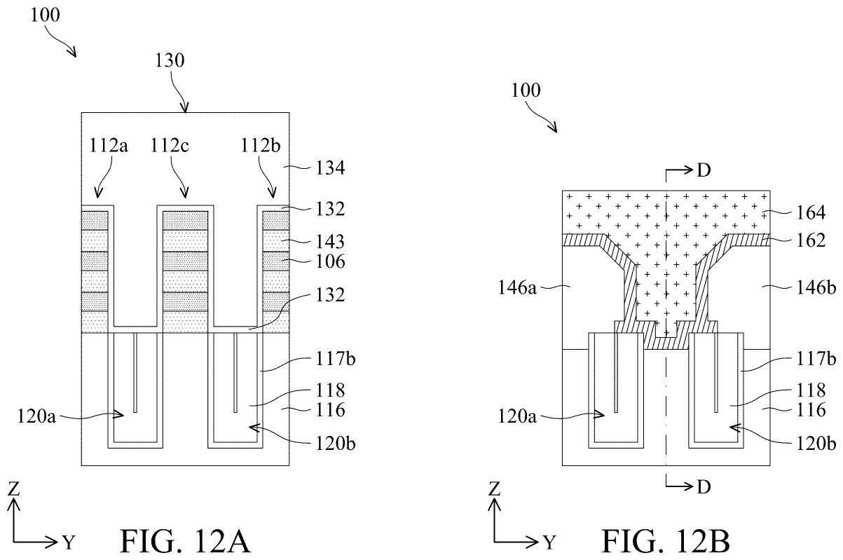

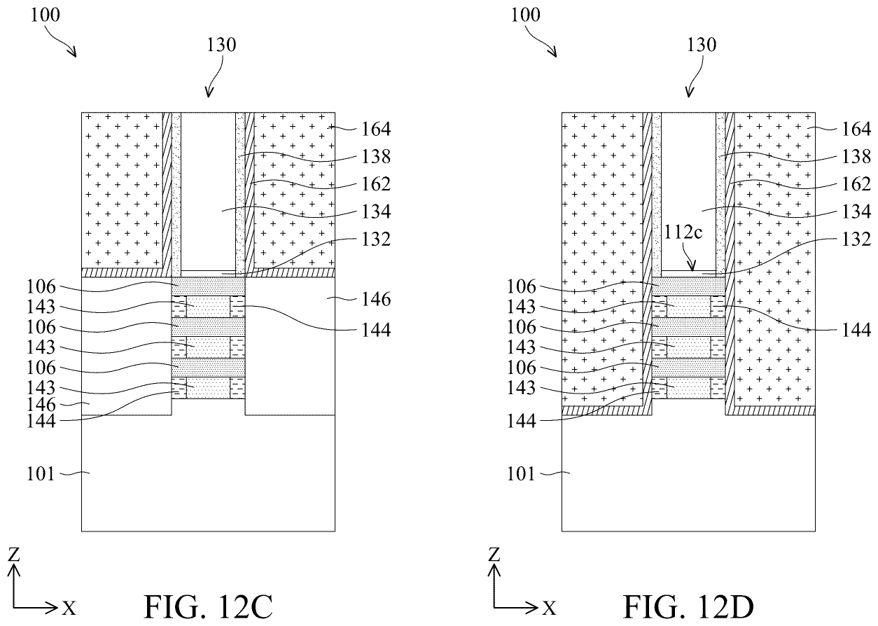

FIGS. 12A, 12B, and 12C are cross-sectional side views of one of various stages of manufacturing the semiconductor device structure 100 taken along line A-A, line B-B, and line C-C of FIG. 6, respectively, in accordance with some embodiments. FIG. 12D is a cross-sectional side view taken along line D-D of FIG. 12B, in accordance with some embodiments. In FIGS. 12A-12D, a contact etch stop layer (CESL) 162 is conformally formed on the exposed surfaces of the semiconductor device structure 100. The CESL 162 covers sidewalls of the sacrificial gate structure 130, the S/D features 146a-b, the isolation regions 120a, 120b, and the substrate portion 116 of the dummy fin structure 112c separating the isolation regions 120a, 120b. In some embodiments, the CESL 162 covers the first semiconductor layers 106 and dielectric spacers 144 of the dummy fin structure 112c as shown in FIG. 12D. The CESL 162 may include a nitrogen-containing material, such as silicon nitride, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, the ILD layer 164 has a dielectric constant (k value) that is about 3 to about 5. In some embodiments, after formation of the ILD layer 164, the semiconductor device structure 100 may be subject to a thermal process to anneal the ILD layer 164. After the ILD layer 164 is formed, a planarization operation, such as CMP, is performed on the semiconductor device structure 100 until the sacrificial gate electrode layer 134 is exposed, as shown in FIGS. 12A-12D.

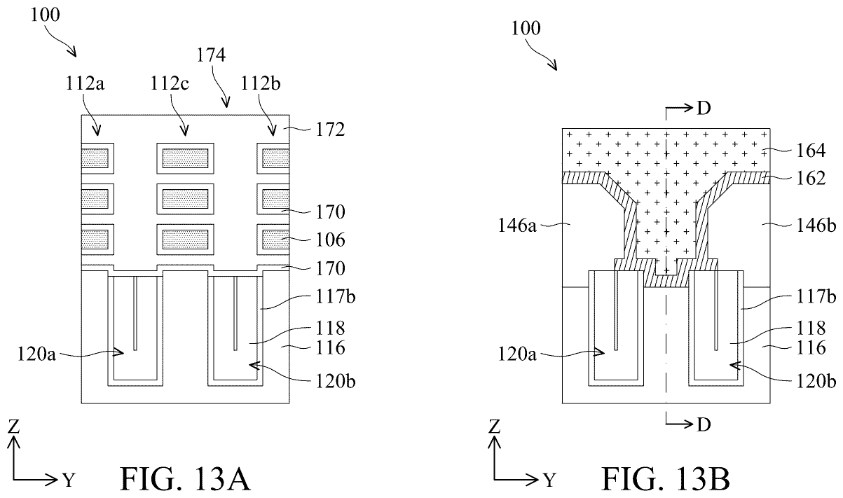

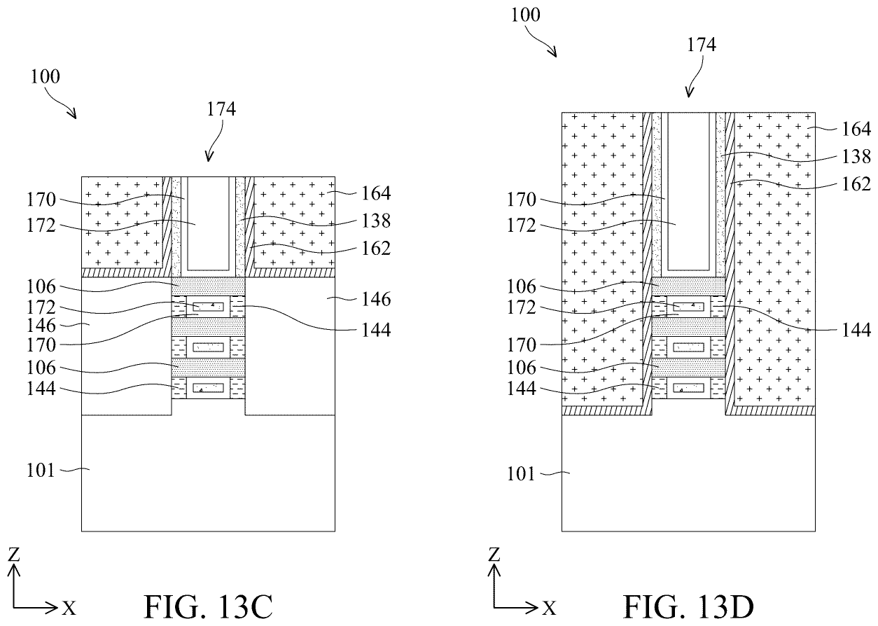

FIGS. 13A, 13B, and 13C are cross-sectional side views of one of various stages of manufacturing the semiconductor device structure 100 taken along line A-A, line B-B, and line C-C of FIG. 6, respectively, in accordance with some embodiments. FIG. 13D is a cross-sectional side view taken along line D-D of FIG. 13B, in accordance with some embodiments. As shown in FIGS. 13A-13D, the sacrificial gate electrode layer 134, the sacrificial gate dielectric layer 132, and the dielectric material 143 are removed, exposing portions of the first semiconductor layer 106. In some embodiments, portions of the isolation regions 120a, 120b are exposed by removal of the sacrificial gate dielectric layer 132. The removal of the sacrificial gate structure 130 and the dielectric material 143 forms an opening between the spacers 138 and between the first semiconductor layers 106. The ILD layer 164 protects the S/D features 146 during the removal processes. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 138, the ILD layer 164, and the CESL 162. In some embodiments, the dielectric material 143 is removed by a selective etch process. The selective etch process removes the dielectric material 143 between the first semiconductor layers 106 but does not remove the first semiconductor layers 106, the ILD layer 164, the CESL 162, and the spacers 138. In some embodiments, the sacrificial gate dielectric layer 132 and the dielectric material 143 are removed by the same selective etch process.

Next, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170, as shown in FIGS. 13A, 13C, and 13D. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. The interfacial layer interfaces the first semiconductor layers 106 (e.g., active region). In some embodiments, the gate dielectric layer 170 is formed over the exposed portions of the isolation regions 120a, 120b as shown in FIG. 13A. For example, the gate dielectric layer 170 and the isolation regions 120a, 120b may intermix at an interface between the gate dielectric layer 170 and the isolation regions 120a, 120b. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material (e.g., one or more metal layers), such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

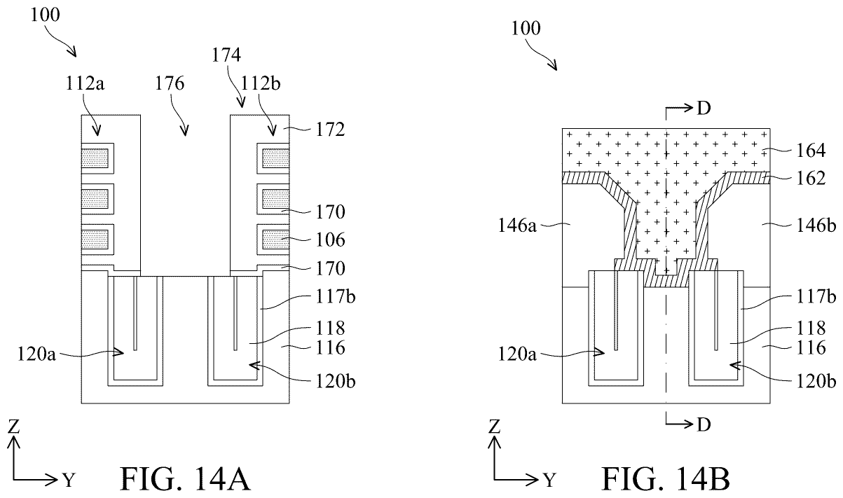

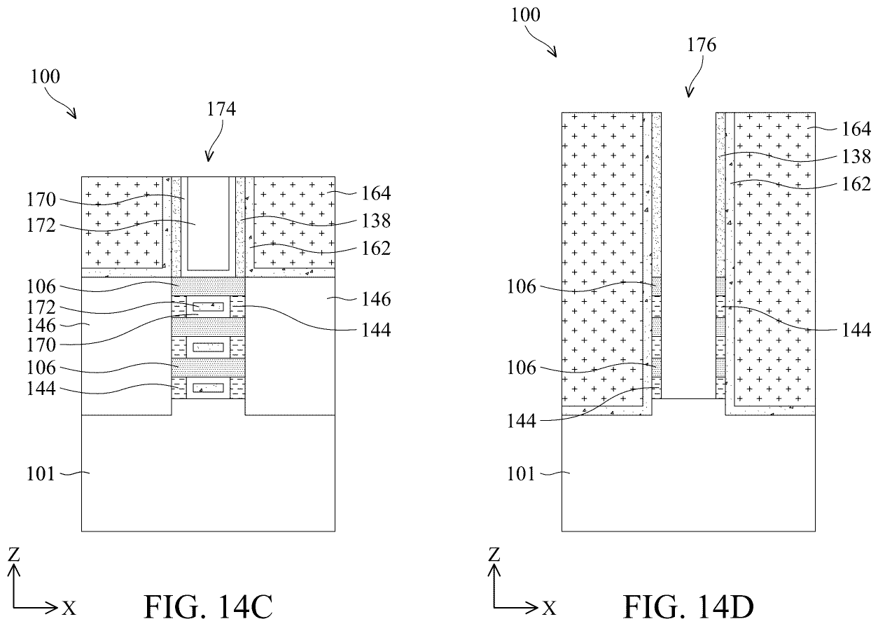

FIGS. 14A, 14B, and 14C are cross-sectional side views of one of various stages of manufacturing the semiconductor device structure 100 taken along line A-A, line B-B, and line C-C of FIG. 6, respectively, in accordance with some embodiments. FIG. 14D is a cross-sectional side view taken along line D-D of FIG. 14B, in accordance with some embodiments. As shown in FIGS. 14A-14D, a portion of the dummy fin structure 112c and a portion of the gate structure 174 that is surrounding the portion of the dummy fin structure 112c are removed. For example, the first semiconductor layers 106, the IL formed on the first semiconductor layers 106, the gate dielectric layers 170 surrounding the first semiconductor layers 106, and the portion of the gate electrode layer 172 surrounding the gate dielectric layers 170 are removed. The removal process forms a trench 176 disposed between the p-channel fin structure 112a and n-channel fin structure 112b and between portions of the gate structure 174 covering the p-channel fin structure 112a and n-channel fin structure 112b. The trench 176 is bounded by the gate structure 174, spacers 138, dielectric spacers 144, and first semiconductor layers 106. In other words, the gate structure 174, spacers 138, dielectric spacers 144, and first semiconductor layers 106 are exposed via the trench 176. The trench 176 extends in the Y direction and is overlapping adjacent isolation regions 120a, 120b as shown in FIG. 14A. In some embodiments, the trench 176 may be formed by patterning a hard mask layer using multi-patterning operations including photo-lithography and etching processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms the trench 176 in unprotected regions through the hard mask layer, through the gate structure 174, through the first semiconductor layers 106 and into the substrate 101. The etching process can include anisotropic etching, such as dry etching, wet etching, reactive ion etching (RIE), and/or other suitable processes.

In some embodiments, as shown in FIG. 14D, the patterned hard mask layer (not shown) is formed on the spacers 138, while the gate dielectric layer 170 and the gate electrode layer 172 are exposed. The anisotropic etching process removes the exposed gate dielectric layer 170, the gate electrode layer 172, and the portions of the first semiconductor layers 106 disposed under the gate dielectric layer 170 and the gate electrode layer 172. The remaining portions of the first semiconductor layers 106 and the dielectric spacers 144 are protected by the spacers 138 during the anisotropic etching process. In some embodiments, the patterned hard mask layer (not shown) is formed on the CESL 162, and the spacers 138 along with the gate dielectric layer 170 and the gate electrode layer 172 are exposed. As a result, the spacers 138, the gate dielectric layer 170, the gate electrode layer 172, the first semiconductor layers 106, and the dielectric spacers 144 shown in FIG. 13D are all removed by the anisotropic etching process. Thus, in some embodiments, the trench 176 is bound by the CESL 162 and the substrate portion 116, as shown in FIG. 14D.

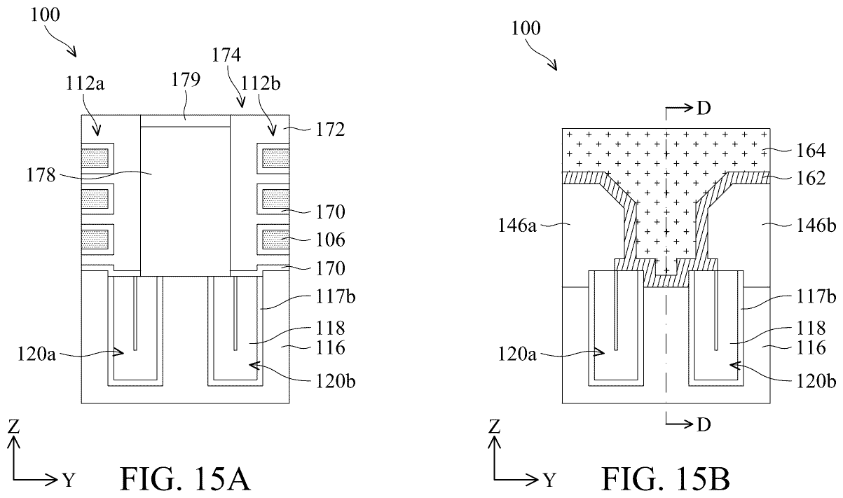

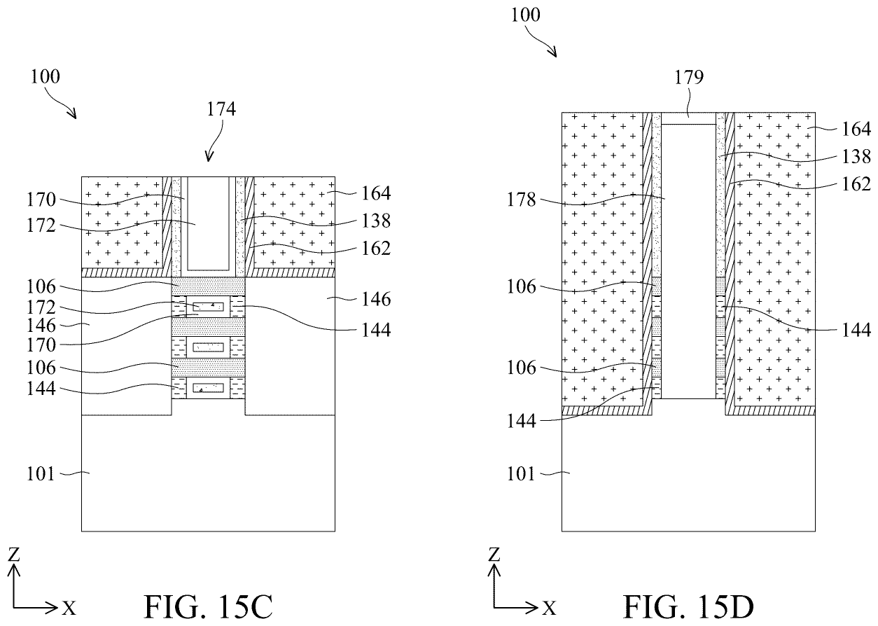

FIGS. 15A, 15B, and 15C are cross-sectional side views of one of various stages of manufacturing the semiconductor device structure 100 taken along line A-A, line B-B, and line C-C of FIG. 6, respectively, in accordance with some embodiments. FIG. 15D is a cross-sectional side view taken along line D-D of FIG. 15B, in accordance with some embodiments. As shown in FIGS. 15A-15D, a dielectric layer 178 is formed in the trench 176. The dielectric layer 178 electrically isolates portions of the gate structure 174 across the trench 176. In some embodiments, the dielectric layer 178 is an oxide-containing dielectric layer, such as an oxide fill layer. The dielectric layer 178 may be formed by any suitable process, such as ALD, CVD, PECVD, or FCVD. In some embodiments, the oxide fill material is silicon oxide. The dielectric layer 178 is recessed and a conductive layer 179 is formed over the dielectric layer 178 in the recessed portion of the dielectric layer 178. The dielectric layer 178 and conductive layer 179 are disposed between the isolation regions 120a, 120b in the Y direction. The conductive layer 179 is formed to electrically connect the portions of the gate structure 174 across the dielectric layer 178. The conductive layer 179 may include one or more conductive materials (e.g., one or more metal layers), such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. In one embodiment, the conductive layer 179 consists of tungsten. The conductive layer 179 may be formed by CVD, ALD, electro-plating, or other suitable deposition technique.

The dielectric layer 178 and conductive layer 179 may reduce a capacitance of the semiconductor device structure 100 compared to some alternative embodiments. For example, in some alternative embodiments, the dummy fin structure 112c may be retained in the final device structure without forming the dielectric layer 178 and conductive layer 179. In such embodiments, the dummy fin structure 112c is disposed between the isolation regions 120a, 120b in the Y direction. In other words, the process steps associated with FIGS. 14-15 may be omitted, and the gate structure 174 and dummy fin structure 112c may be retained as shown in FIGS. 13A-13D, although the capacitance may exceed that of the semiconductor device structure 100 shown in FIGS. 15A-15D.

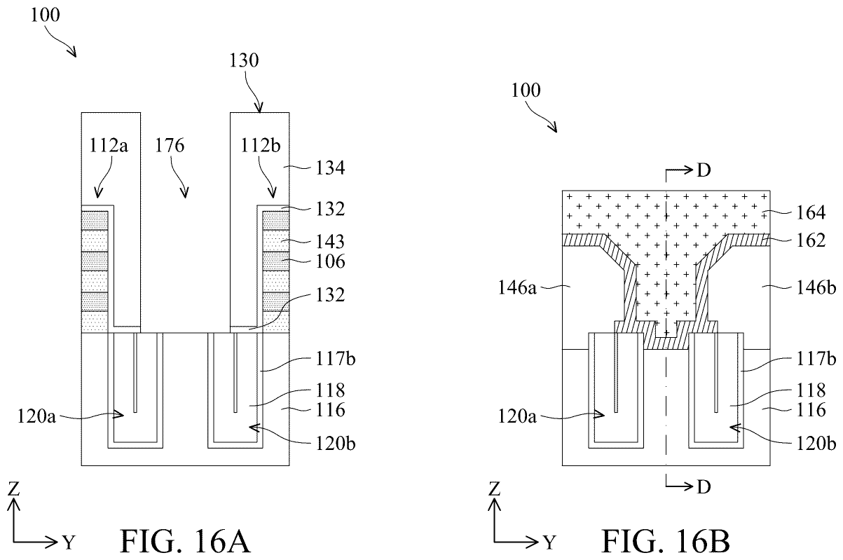

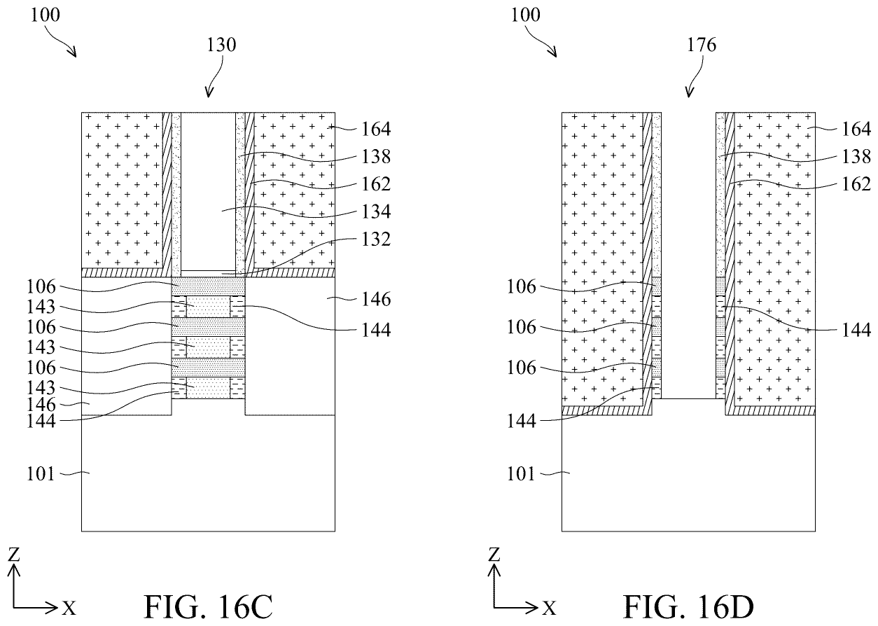

FIGS. 16-18 illustrate an alternative process for gate replacement and forming the dielectric layer 178 and conductive layer 179. In some embodiments, the process flow illustrated in FIGS. 16-18 would follow directly after the manufacturing stage shown in FIGS. 12A-12D. As shown in FIGS. 16A-16D, a trench 176 is formed by removing the dummy fin structure 112c before replacement of the sacrificial gate structure 130 with the gate structure 174. In some embodiments, the first semiconductor layers 106, the dielectric material 143, the sacrificial gate dielectric layers 132, and the portion of the sacrificial gate electrode layer 134 are removed. The process of forming the trench 176 is the same as, or similar to, the process described in connection with FIGS. 14A-14D, except for the sacrificial gate structure 130 and the dielectric material 143 being in place of the gate structure 174. In some embodiments, removing a portion of the sacrificial gate structure 130 to form the trench 176 may be a relatively less selective process compared to removing a portion of the gate structure 174 because of differing material compositions. For instance, the removal process for polycrystalline silicon material associated with the sacrificial gate structure 130 may be relatively less selective compared to the removal process for metal material associated with the gate structure 174.

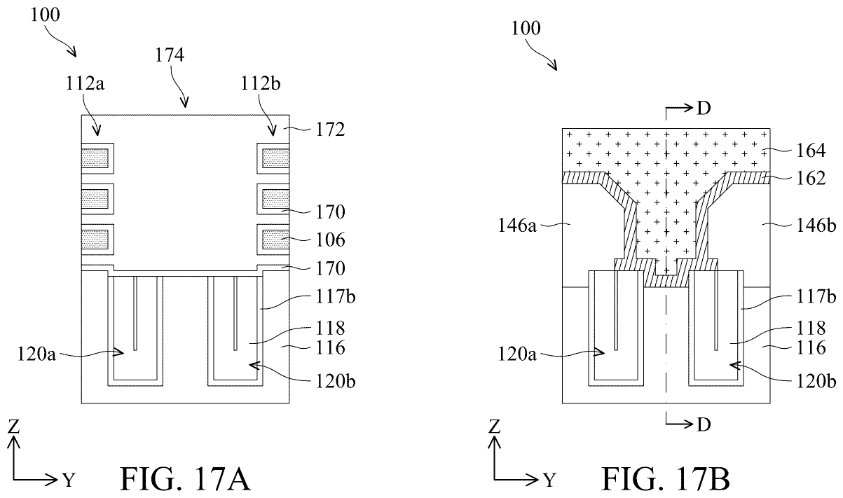

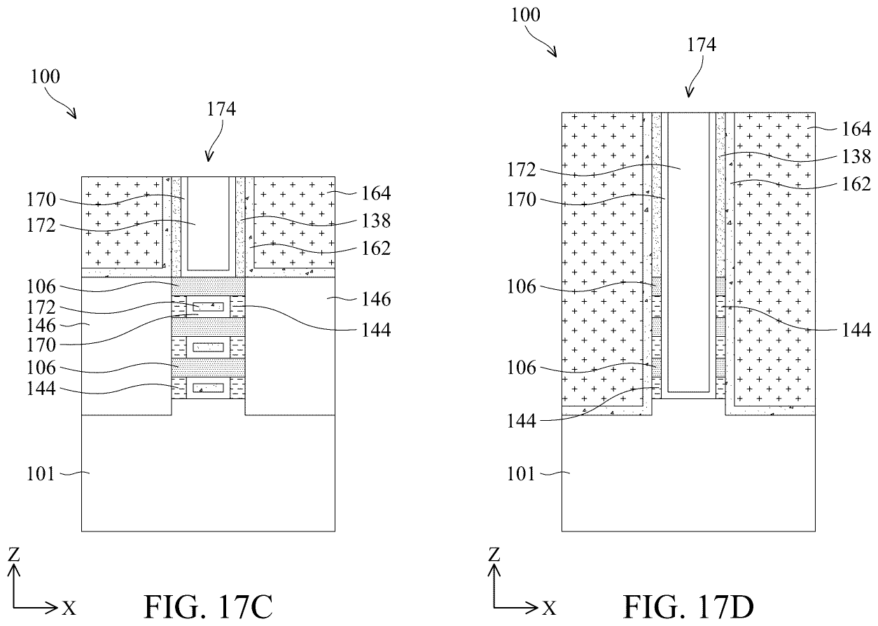

As shown in FIGS. 17A-17D, removal of the sacrificial gate structure 130 to form the nanostructure channel and subsequent formation of the gate structure 174 are performed using the same or similar process to that described in connection with FIGS. 13A-13D. In some embodiments, because the portion of the dummy fin structure 112c is removed and the trench 176 is formed before gate replacement, the gate structure 174 fills in the trench 176 as shown in FIGS. 17A and 17D.

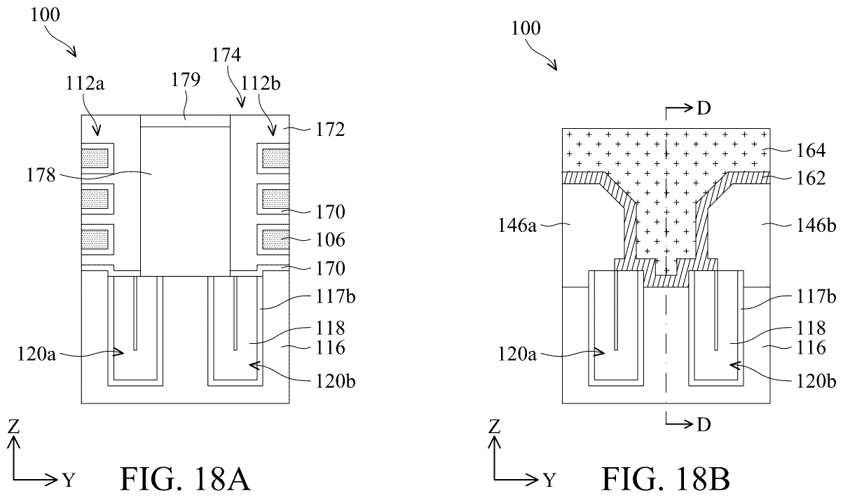

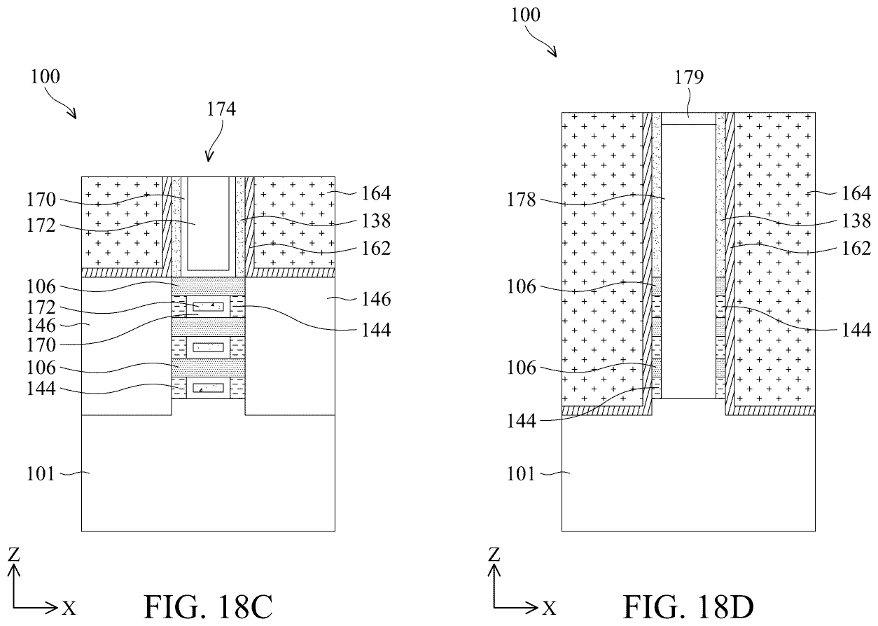

As shown in FIGS. 18A-18D, the dielectric layer 178 and conductive layer 179 are formed using the same or similar process to that described in connection with FIGS. 15A-15D. Because the gate structure 174 fills in the trench 176, the process may include an additional multi-patterning operation similar to that described in connection with FIGS. 14A-14D to reform the trench prior to deposition of the dielectric layer 178. As shown in FIG. 18D, the dielectric spacers 144 remain between the dielectric layer 178 and the CESL 162. However, in some other embodiments, the dielectric spacers 144 may be removed such that the dielectric layer 178 is disposed on the CESL 162.

In some alternative embodiments, the dielectric layer 178 and conductive layer 179 may be formed in the trench 176 prior to gate replacement, in which case removal of the remaining portions of the sacrificial gate structure 130 to form the nanostructure channel and subsequent formation of the gate structure 174 may be performed without affecting the dielectric layer 178 and conductive layer 179 by protecting those layers by patterning a hard mask layer using multi-patterning operations including photo-lithography and etching processes as described elsewhere herein.

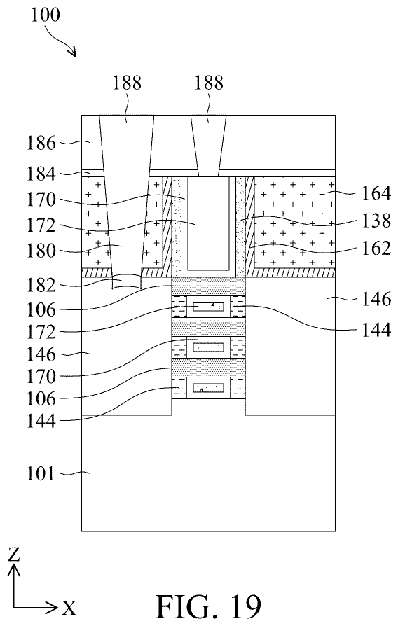

As shown in FIG. 19, S/D contacts 180 are formed in the ILD layer 164 and the CESL 162. The S/D contact 180 is electrically connected to the corresponding S/D feature 146 via a silicide layer 182. The S/D contact 180 may be electrically conductive and may include a material having one or more of Ru, Mo, Co, Ir, W, Ti, Ta, Cu, TiN or TaN. The S/D contacts 180 may be formed by any suitable method, such as electro-chemical plating (ECP) or PVD. The silicide layers 182 may be metal silicide layers formed by any suitable process. As shown in FIG. 19, the silicide layer 182 has a curved profile. In some embodiments, an electrical conductivity of the silicide layer 182 is between an electrical conductivity of the respective S/D feature 146 and an electrical conductivity of the respective S/D contact 180. In some embodiments, a metal layer (not shown) is first formed on the semiconductor device structure 100. The metal layer may include Ti, Ni, Ru, Co, W, or other suitable metal. The metal layer may be deposited by any suitable process, such as ALD, CVD, or PVD. After the metal layer deposition, an annealing process is performed to react the S/D features 146 with the metal layer, thereby forming the silicide layers 182. The silicide layer 182 may include any suitable material, such as NiSi, TiSi, CoSi, RuSi, or WSi. A planarization process, such as a CMP process, may be performed so the top surfaces of the gate electrode layers 172 and the top surfaces of the S/D contacts 180 are substantially co-planar, as shown in FIG. 19. In some embodiments, the S/D contact 180 has a critical dimension ranging from about 5 nm to about 50 nm. In some embodiments, the S/D contact 180 may be formed on a liner. The liner may include any suitable dielectric material, such as SiN. However, as shown in FIG. 19, the liner is not present, and the S/D contact 180 is in contact with the ILD layer 164.

Next, as shown in FIG. 19, an etch stop layer 184 is formed on the ILD layer 164, the gate structures 174, and the S/D contacts 180. The etch stop layer 184 may be referred to as a middle contact etch stop layer (MCESL). An ILD layer 186 is formed on the etch stop layer 184. In some embodiments, the etch stop layer 184 may include a material different from the CESL 162. For example, the CESL 162 may be made from SiN, and the etch stop layer 184 may be made from a dielectric material having a k value less than that of the CESL 162. In some embodiments, the etch stop layer 184 may include SiO2, Si3N4, SiC, other metal oxides, other suitable materials, and combinations thereof. The etch stop layer 184 may be deposited by a CVD process, PECVD process, or other suitable deposition technique. The ILD layer 186 may include the same material as the ILD layer 164. The ILD layer 186 may be deposited by a PECVD process or other suitable deposition technique.

As shown in FIG. 19, conductive contacts 188 are deposited in the ILD layer 186 and the etch stop layer 184. The conductive contact 188 may include an electrically conductive material, such as Ru, Mo, Co, Ir, W, Ti, Ta, Cu, TiN, TaN or combinations thereof, or other suitable material. The conductive contact 188 may be formed by any suitable process, such as PVD or ECP. In some embodiments, the conductive contacts 188 are electrically connected to the gate electrode layers 172 and/or the S/D contacts 180.

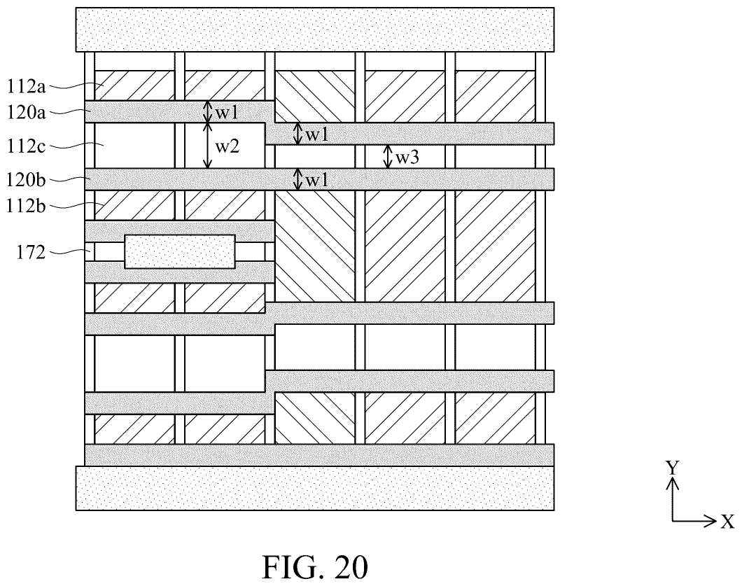

FIG. 20 is a top view of the semiconductor device structure 100, in accordance with some embodiments. In some embodiments, as shown in FIG. 20, the fin structures 112a, 112b have varying widths along the Y direction. As a result, the area between the fin structures 112a, 112b has varying widths. As described above, the isolation regions 120a, 120b have fixed width W1. Thus, the dummy fin structure 112c has varying widths W2, W3, as shown in FIG. 20. By using the dummy fin structure 112c, the trenches 114 (FIG. 2) have the same widths, which can be filled by a non-flowable process. By using a non-flowable process, the Dit is reduced.

Embodiments of the present disclosure provide a semiconductor device structure 100 including isolation regions 120a, 120b formed via a fixed size STI etch. The fixed size STI etch provides for the fabrication of non-flowable isolation regions (e.g., formed via ALD) to improve ability to manage gaps with a range of different sizes. Therefore, instead of performing an STI etch that covers various different spacings between active regions, the etching process disclosed herein uses a fixed size that leaves an area that is not etched, which results in a dummy fin structure positioned laterally between two isolation regions, and optionally includes an extra process step to add a dielectric layer in place of the dummy fin structure.

An embodiment is a semiconductor device structure. The semiconductor device structure includes an active region; an isolation region disposed alongside the active region; a gate structure over the active region, wherein the gate structure comprises an interfacial layer, a gate dielectric layer over the interfacial layer, and at least one metal layer over the gate dielectric layer, wherein the interfacial layer interfaces the active region, wherein the gate dielectric layer and the isolation region intermix at an interface between the gate dielectric layer and the isolation region; an interlayer dielectric (ILD) layer disposed over the isolation region, wherein the ILD layer has a dielectric constant that is about 3 to about 5; and an etch stop layer disposed between the ILD layer and the isolation region, wherein the isolation region comprises a nitride-containing dielectric layer, and wherein a width of the isolation region is less than 10 nm.

Another embodiment is a semiconductor device structure. The semiconductor device structure includes a first active region and a second active region comprising first and second respective channel regions and first and second respective source/drain regions adjacent to the first and second respective channel regions; a gate structure over the first and second respective channel regions; first and second respective source/drain features over the first and second respective source/drain regions; a source/drain contact electrically coupled to one of the first or second respective source/drain features by way of a metal silicide layer; a first isolation region and a second isolation region disposed between the first active region and the second active region; a semiconductor substrate portion disposed between the first isolation region and the second isolation region, wherein the first isolation region and the second isolation region comprise a nitride-containing material; and an interlayer dielectric (ILD) layer disposed over the first and second respective source/drain features, wherein the source/drain contact is disposed in the ILD layer, and wherein an electrical conductivity of the metal silicide layer is between an electrical conductivity of the first and second respective source/drain features and an electrical conductivity of the source/drain contact, wherein the metal silicide layer comprises a curved profile.

A further embodiment is a method. The method includes performing forming an active region; forming an isolation region alongside the active region, wherein the isolation region includes a first shallow trench isolation (STI) region adjacent the active region in a first direction and a second STI region spaced from the first STI region in the first direction such that the first STI region is between the active region and the second STI region, and wherein the first STI region and the second STI region are separated by a semiconductor substrate portion; forming a sacrificial gate structure over the active region; forming a source/drain feature; forming a contact etch stop layer on the semiconductor substrate portion; forming an interlayer dielectric (ILD) layer over the contact etch stop layer; removing the sacrificial gate structure; forming a gate structure over the active region, wherein the gate structure comprises an interfacial layer, a gate dielectric layer over the interfacial layer, and at least one metal layer over the gate dielectric layer, wherein the interfacial layer interfaces the active region, wherein the gate dielectric layer and the isolation region intermix at an interface between the gate dielectric layer and the isolation region; forming a source/drain contact disposed in the ILD layer to electrically couple to the source/drain feature; and forming a metal silicide layer between the source/drain feature and the source/drain contact, wherein an electrical conductivity of the metal silicide layer is between an electrical conductivity of the source/drain feature and an electrical conductivity of the source/drain contact, wherein the metal silicide layer comprises a curved profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
an active region;
an isolation region disposed alongside the active region;
a gate structure over the active region, wherein the gate structure comprises an interfacial layer, a gate dielectric layer over the interfacial layer, and at least one metal layer over the gate dielectric layer, wherein the interfacial layer interfaces the active region, wherein the gate dielectric layer and the isolation region intermix at an interface between the gate dielectric layer and the isolation region;
an interlayer dielectric (ILD) layer disposed over the isolation region, wherein the ILD layer has a dielectric constant that is about 3 to about 5; and
an etch stop layer disposed between the ILD layer and the isolation region, wherein the isolation region comprises a nitride-containing dielectric layer, and wherein a width of the isolation region is less than 10 nm.

2. The semiconductor device structure of claim 1, wherein the active region is a first active region, further comprising a second active region, wherein the gate structure is over the first active region and the second active region, wherein the isolation region includes a first shallow trench isolation (STI) region adjacent the first active region and a second STI region adjacent the second active region, wherein the first STI region and second STI region are between the first active region and the second active region, and wherein the first STI region and the second STI region are separated by a semiconductor substrate portion.

3. The semiconductor device structure of claim 2, wherein the first STI region and the second STI region have a first width, and wherein a first distance between the first and second active regions is greater than two times the first width.

4. The semiconductor device structure of claim 2, wherein the etch stop layer is disposed on the semiconductor substrate portion.

5. The semiconductor device structure of claim 2, further comprising a dummy fin structure between the first STI region and the second STI region under the gate structure.

6. The semiconductor device structure of claim 5, wherein the dummy fin structure comprises a plurality of semiconductor layers surrounded by the gate structure and the semiconductor substrate portion located under the plurality of semiconductor layers.

7. The semiconductor device structure of claim 3, further comprising a third active region and a fourth active region, wherein a second distance between the third active region and the fourth active region is different from the first distance between the first active region and the second active region, and further comprising a third STI region and a fourth STI region between the third active region and the fourth active region, wherein a second width of the third STI region and the fourth STI region is equal to the first width of the first STI region and the second STI region.

8. A semiconductor device structure, comprising:
a first active region and a second active region comprising first and second respective channel regions and first and second respective source/drain regions adjacent to the first and second respective channel regions;
a gate structure over the first and second respective channel regions;
first and second respective source/drain features over the first and second respective source/drain regions;
a source/drain contact electrically coupled to one of the first or second respective source/drain features by way of a metal silicide layer;
a first isolation region and a second isolation region disposed between the first active region and the second active region;
a semiconductor substrate portion disposed between the first isolation region and the second isolation region, wherein the first isolation region and the second isolation region comprise a nitride-containing material; and
an interlayer dielectric (ILD) layer disposed over the first and second respective source/drain features, wherein the source/drain contact is disposed in the ILD layer, and wherein an electrical conductivity of the metal silicide layer is between an electrical conductivity of the first and second respective source/drain features and an electrical conductivity of the source/drain contact, wherein the metal silicide layer comprises a curved profile.

9. The semiconductor device structure of claim 8, further comprising a contact etch stop layer disposed on the semiconductor substrate portion.

10. The semiconductor device structure of claim 8, wherein the first isolation region and the second isolation region have a first width, and wherein a first distance between the first and second active regions is greater than two times the first width.

11. The semiconductor device structure of claim 10, further comprising a third active region and a fourth active region, wherein a second distance between the third active region and the fourth active region is different from the first distance between the first active region and the second active region, and further comprising third and fourth isolation regions between the third active region and the fourth active region, wherein a second width of the third and fourth isolation regions is equal to the first width of the first and second isolation regions.

12. The semiconductor device structure of claim 8, further comprising an oxide-containing dielectric layer between the first and second isolation regions.

13. The semiconductor device structure of claim 8, further comprising a dummy fin structure between the first isolation region and the second isolation region under the gate structure.

14. The semiconductor device structure of claim 8, wherein a width of the first and second isolation regions is less than 10 nm.

15. A method, comprising:
forming an active region;
forming an isolation region alongside the active region, wherein the isolation region includes a first shallow trench isolation (STI) region adjacent the active region in a first direction and a second STI region spaced from the first STI region in the first direction such that the first STI region is between the active region and the second STI region, and wherein the first STI region and the second STI region are separated by a semiconductor substrate portion;
forming a sacrificial gate structure over the active region;
forming a source/drain feature;
forming a contact etch stop layer on the semiconductor substrate portion;
forming an interlayer dielectric (ILD) layer over the contact etch stop layer;
removing the sacrificial gate structure;
forming a gate structure over the active region, wherein the gate structure comprises an interfacial layer, a gate dielectric layer over the interfacial layer, and at least one metal layer over the gate dielectric layer, wherein the interfacial layer interfaces the active region, wherein the gate dielectric layer and the isolation region intermix at an interface between the gate dielectric layer and the isolation region;
forming a source/drain contact disposed in the ILD layer to electrically couple to the source/drain feature; and
forming a metal silicide layer between the source/drain feature and the source/drain contact, wherein an electrical conductivity of the metal silicide layer is between an electrical conductivity of the source/drain feature and an electrical conductivity of the source/drain contact, wherein the metal silicide layer comprises a curved profile.

16. The method of claim 15, wherein forming the isolation region includes forming the first and second STI regions by depositing an insulating material via atomic layer deposition.

17. The method of claim 15, further comprising forming an oxide-containing dielectric layer between the first STI region and the second STI region.

18. The method of claim 17, wherein forming the oxide-containing dielectric layer comprises:
after removing the sacrificial gate structure and forming the gate structure, removing a dummy device structure that is between the first and second STI regions to form a trench; and
forming the oxide-containing dielectric layer in the trench.

19. The method of claim 17, wherein forming the oxide-containing dielectric layer comprises:
before removing the sacrificial gate structure, removing a dummy device structure that is between the first and second STI regions to form a trench; and
after forming the gate structure, forming the oxide-containing dielectric layer.

20. The method of claim 17, further comprising forming a conductive layer over the oxide-containing dielectric layer.
